(19) United States
(12) Patent Application Publication
(10) Pub. No.: US 2019/0006919 A1
(43) Pub. Date: Jan. 3, 2019

(54) MOTOR SYSTEM AND MOTOR CONTROL METHOD

(71) Applicant: Lite-On Technology Corporation, Taipei (TW)

(72) Inventor: Chun-Lung Ho, Taipei (TW)

(73) Assignee: Lite-On Technology Corporation, Taipei (TW)

(21) Appl. No.: 15/698,665

(22) Filed: Sep. 8, 2017

(30) Foreign Application Priority Data
Jun. 28, 2017 (TW) 106121538

(51) Int. Cl. H02K 11/35; H02K 11/21; G01R 31/34

(52) U.S. Cl. CPC H02K 11/35; G01R 31/343; H02K 11/21

(57) ABSTRACT

A motor system and a motor control method are provided. The motor system includes a motor apparatus. The motor apparatus includes a stator-rotor portion and a storage. The stator-rotor portion is configured to receive driving electric energy and generate mechanical energy in response to the driving electric energy. The storage is configured to store actual characteristic data of the motor apparatus, and the actual characteristic data serves as a basis of controlling the motor apparatus or identifying the motor apparatus.

### CROSS REFERENCE TO RELATED APPLICATION

This application claims the priority benefit of Taiwan application serial no. 106121538, filed on Jun. 28, 2017. The entirety of the above-mentioned patent application is hereby incorporated by reference herein and made a part of specification.

### BACKGROUND OF THE INVENTION

### Field of the Invention

The invention relates to motor technology and more particularly relates to a high performance motor system and a motor control method for improving motor performance.

### Description of Related Art

Generally, motor manufacturers will provide uniform product specification for motors. Therefore, the existing motor control technique is usually to input the product specification of the motors provided by the manufacturers into a driver for the driver to control the motors according to the product specification. However, due to variation of the motor production processes and the raw materials used for the motors, the uniform product specification provided by the manufacturers may not be the actual specification of each motor. In other words, the actual characteristic of each motor may often differ from the characteristic in the uniform product specification provided by the manufacturers. Thus, when the driver controls the motor according to the product specification described above, the driver and the motor may not achieve optimal coordination, and as a result, the overall performance of the motor system may not be optimized.

In addition, the housing of the motor usually has a bar code label thereon for recording production data of the motor, e.g., production date, model number, rated rotating speed, rated current, and rated torque of the motor. When the motor is in need of repair or maintenance, basic data and characteristics of the motor may be obtained from the bar code label on the motor, so as to determine the appropriate treatments. However, the bar code label on the motor may come off due to usage of end customers or influence of the environment. Once the bar code label comes off or is lost, it will be difficult to determine the basic data and characteristics of the motor, which hinders the repair or maintenance.

### SUMMARY OF THE INVENTION

In view of the above, the invention provides a motor system and a motor control method for storing actual characteristic data of a motor apparatus in a storage of the motor apparatus, wherein the stored actual characteristic data may serve as a basis of controlling the motor apparatus or identifying the motor apparatus, thereby optimizing performance of the motor system and facilitating tracking and clarifying the problem that the motor apparatus may have in the future.

The invention provides a motor system that includes a motor apparatus. The motor apparatus includes a stator-rotor portion and an encoder circuit. The stator-rotor portion receives driving electric energy. The encoder circuit is electrically coupled to the stator-rotor portion. The encoder circuit includes a storage. The storage stores actual characteristic data of the motor apparatus.

In an embodiment of the invention, the motor system further includes a driver. The driver is electrically coupled to the stator-rotor portion and the storage. When the driver is activated, the driver reads the actual characteristic data of the motor apparatus from the storage, and generates the driving electric energy according to the actual characteristic data.

In an embodiment of the invention, the actual characteristic data includes at least one motor characteristic. The at least one motor characteristic is a coil inductance, a coil impedance, a back electromotive force, a maximum rotating speed, a rated current, a rated torque, a maximum torque, a torque constant, or a power factor of the motor apparatus.

In an embodiment of the invention, the actual characteristic data includes a production history of manufacturing of the motor apparatus. The production history includes a production date, a production site, a motor type, or a product model number of the motor apparatus.

In an embodiment of the invention, the actual characteristic data further includes at least one motor characteristic. The at least one motor characteristic is obtained through a test that a motor product testing machine performs on the motor apparatus via a driver, and the motor product testing machine stores the at least one motor characteristic and the production history to the storage via the driver.

In an embodiment of the invention, the encoder circuit further includes a feedback encoder. The feedback encoder is coupled to the driver and detects an operation state of the stator-rotor portion to generate a feedback detection signal. The driver further generates the driving electric energy according to the feedback detection signal.

The invention provides a motor control method that includes the following. Actual characteristic data of a motor apparatus is stored in a storage of the motor apparatus. The motor apparatus is identified based on the actual characteristic data, or the motor apparatus is controlled based on the actual characteristic data, such that a stator-rotor portion of the motor apparatus generates mechanical energy in response to driving electric energy.

Based on the above, in the motor system and the motor control method disclosed in the embodiments of the invention, the actual characteristic data of the motor apparatus is stored in the storage of the motor apparatus, wherein the stored actual characteristic data may serve as a basis of controlling the motor apparatus or identifying the motor apparatus, thereby optimizing performance of the motor system and facilitating tracking and clarifying the problem that the motor apparatus may have in the future.

To make the aforementioned and other features and advantages of the invention more comprehensible, several embodiments accompanied with figures are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a block diagram showing a motor system according to an embodiment of the invention.

FIG. 2 is a block diagram showing a motor system according to another embodiment of the invention.

FIG. 3 is a flowchart showing a motor control method according to an embodiment of the invention.

FIG. 4 is a flowchart showing detailed steps of Step S300 of FIG. 3 according to an embodiment of the invention.

FIG. 5 is a flowchart showing detailed steps of Step S320 of FIG. 3 according to an embodiment of the invention.

### DESCRIPTION OF THE EMBODIMENTS

In order to make the invention more comprehensible, several embodiments are described below as examples of implementation of the invention. In addition, wherever possible, identical or similar reference numerals stand for identical or similar elements/components in the figures and embodiments.

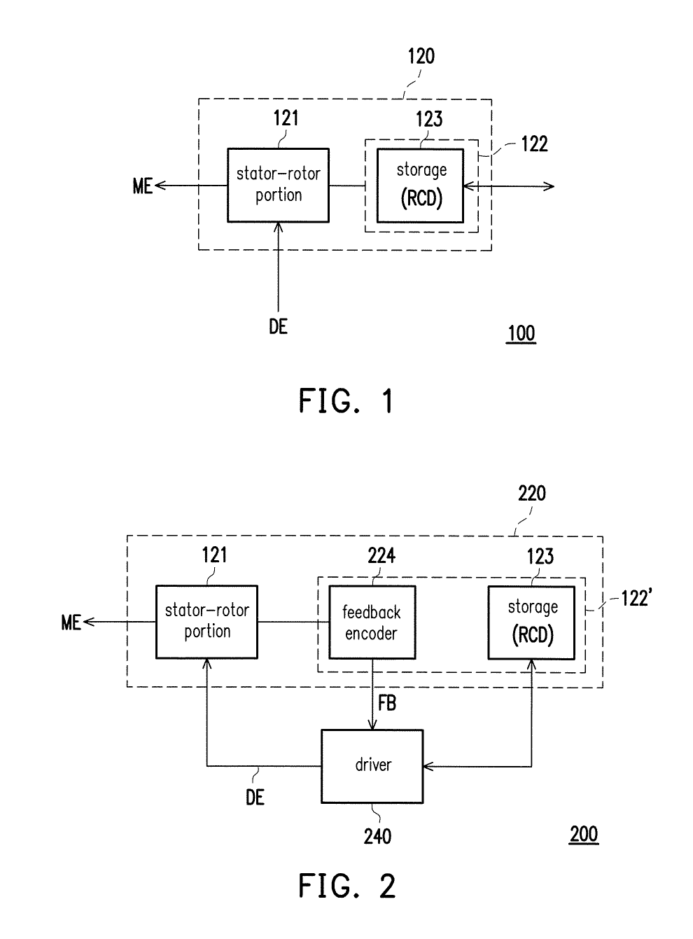

Hereinafter, referring to FIG. 1, FIG. 1 is a block diagram showing a motor system according to an embodiment of the invention. The motor system 100 includes a motor apparatus 120. The motor apparatus 120 may be any type of motor, and the invention is not intended to limit the motor apparatus 120 to a certain type. The motor apparatus 120 may include a stator-rotor portion 121 and an encoder circuit 122, but the invention is not limited thereto. The stator-rotor portion 121 may be composed of a rotor coil and a stator coil, but the invention is not limited thereto. The stator-rotor portion 121 is configured to receive driving electric energy DE and generate mechanical energy ME in response to the driving electric energy DE. The operation of the stator-rotor portion 121 is commonly known to those skilled in the art and thus is not described in detail here.

The encoder circuit 122 is electrically coupled to the stator-rotor portion 121 to detect an operation state of the stator-rotor portion 121. In particular, the encoder circuit 122 includes a storage 123. The storage 123 is configured to store actual characteristic data RCD of the motor apparatus 120, and the actual characteristic data RCD may serve as a basis of controlling the motor apparatus 120 or identifying the motor apparatus 120.

In an embodiment of the invention, the actual characteristic data RCD of the motor apparatus 120 includes at least one motor characteristic obtained by performing a test on the motor apparatus 120, wherein the at least one motor characteristic may include a coil inductance, a coil impedance, a back electromotive force, a maximum rotating speed, a rated current, a rated torque, a maximum torque, a torque constant, or a power factor of the stator-rotor portion 121, but the invention is not limited thereto. Because the actual characteristic data RCD of the motor apparatus 120 is obtained by performing the test on the motor apparatus 120, the actual characteristic data RCD stored in the storage 123 is the real motor characteristic of the motor apparatus 120 itself. It can be understood that, due to variation of the motor production processes and difference in the raw materials used for the motor, the real motor characteristics obtained by performing the test on different motor apparatuses may not be identical. Thus, controlling the motor apparatus 120 based on the real motor characteristic of the motor apparatus 120 itself may reduce occurrence of an error in the actual operation of the motor apparatus 120, so as to effectively improve performance of the motor system 100.

In another embodiment of the invention, the actual characteristic data RCD of the motor apparatus 120 may further include a production history of manufacturing of the motor apparatus 120, wherein the production history may include a production date, a production site, a motor type, or a motor product model number of the motor apparatus 120, but the invention is not limited thereto. The production history may be used for identifying the motor apparatus 120. When the motor apparatus 120 is in need of repair or maintenance, even if a bar code label on the motor apparatus 120 has come off or been lost, the production history stored in the motor apparatus 120 may still be used for tracking and clarifying the problem.

In an embodiment of the invention, the storage 123 may be implemented by a non-volatile memory component, such as a read-only memory (ROM), an erasable programmable read-only memory (EPROM), an electrically-erasable programmable read-only memory (EEPROM), or a flash memory, but the invention is not limited thereto.

Hereinafter, referring to FIG. 2, FIG. 2 is a block diagram showing a motor system according to another embodiment of the invention. The motor system 200 may include a motor apparatus 220 and a driver 240, but the invention is not limited thereto. The motor apparatus 220 may include a stator-rotor portion 121 and an encoder circuit 122′, but the invention is not limited thereto. The encoder circuit 122′ may include a storage 123 and a feedback encoder 224. The stator-rotor portion 121 and the storage 123 of FIG. 2 are similar to the stator-rotor portion 121 and the storage 123 of FIG. 1 respectively and are as described above with reference to FIG. 1, and thus are not repeated here. An operation of the feedback encoder 224 is described in detail later.

The driver 240 is electrically coupled to the stator-rotor portion 121, the storage 123, and the feedback encoder 224. When the driver 240 is activated, the driver 240 may read the actual characteristic data RCD of the motor apparatus 220 from the storage 123 of the motor apparatus 220. The driver 240 may generate driving electric energy DE according to the actual characteristic data RCD to control the motor apparatus 220. As described above, because the actual characteristic data RCD stored in the storage 123 is the real motor characteristic of the motor apparatus 220 itself, when the driver 240 controls the operation of the motor apparatus 220 according to the real motor characteristic of the motor apparatus 220, coordination between the driver 240 and the motor apparatus 220 is optimized to effectively improve the overall performance of the motor system 200. It is worth mentioning that, when the motor apparatus 220 is used in combination with a different driver, the driver may achieve optimal coordination with the motor apparatus 220 as long as the driver reads the actual characteristic data RCD of the motor apparatus 220 and controls the motor apparatus 220 according to the actual characteristic data RCD. In other words, any driver that is capable of reading the actual characteristic data RCD of the motor apparatus 220 and controlling the motor apparatus 220 accordingly is able to achieve optimal coordination with the motor apparatus 220. Therefore, selection of the driver for the motor apparatus 220 is more flexible.

In an embodiment of the invention, the driver 240 may perform a positioning control, an operation speed control, or a torque control on a rotor in the stator-rotor portion 121 based on the actual characteristic data RCD of the motor apparatus 220, wherein the positioning control, the operation speed control, and the torque control may be implemented by a known motor control algorithm and thus is not repeated here.

In an embodiment of the invention, the driver 240 may read the production history in the actual characteristic data RCD to identify the motor apparatus 220. Identification of the motor apparatus 220 has been specified above with reference to FIG. 1 and thus is not repeated here.

In an embodiment of the invention, at least one motor characteristic in the actual characteristic data RCD may be obtained through a test that a motor product testing machine (not shown) performs on the motor apparatus 220 via the driver 240. Moreover, the motor product testing machine may store the actual characteristic data RCD (including the at least one motor characteristic and the production history) to the storage 123 of the motor apparatus 220 via the driver 240. Furthermore, in an embodiment of the invention, the driver 240 may include a RS485 communication interface, and the motor product testing machine may be coupled to the RS485 communication interface of the driver 240. The motor product testing machine may perform the test on the motor apparatus 220 via the RS485 communication interface of the driver 240, or write the actual characteristic data RCD to the storage 123 of the motor apparatus 220 via the RS485 communication interface of the driver 240 and a software tool, but the invention is not limited thereto. In another embodiment of the invention, the motor product testing machine may directly perform the test on the motor apparatus 220, and directly write the actual characteristic data RCD to the storage 123 of the motor apparatus 220.

The operation of the feedback encoder 224 is described hereinafter. The feedback encoder 224 is coupled to the driver 240. The feedback encoder 224 detects the operation state of the stator-rotor portion 121 (e.g., position or speed of the rotor) to generate a feedback detection signal FB. The driver 240 receives the feedback detection signal FB. The driver 240 may generate the driving electric energy DE according to the feedback detection signal FB and the actual characteristic data RCD to perform control, e.g., the positioning control, the operation speed control, or the torque control, on the motor apparatus 220. As described above, the positioning control, the operation speed control, and the torque control may be implemented by a known motor control algorithm and thus is not repeated here.

In an embodiment of the invention, the feedback encoder 224 may be implemented by a known feedback encoding integrated circuit and disposed on a printed circuit board in the motor apparatus 220. In an embodiment of the invention, the storage 123 may also be disposed on the printed circuit board.

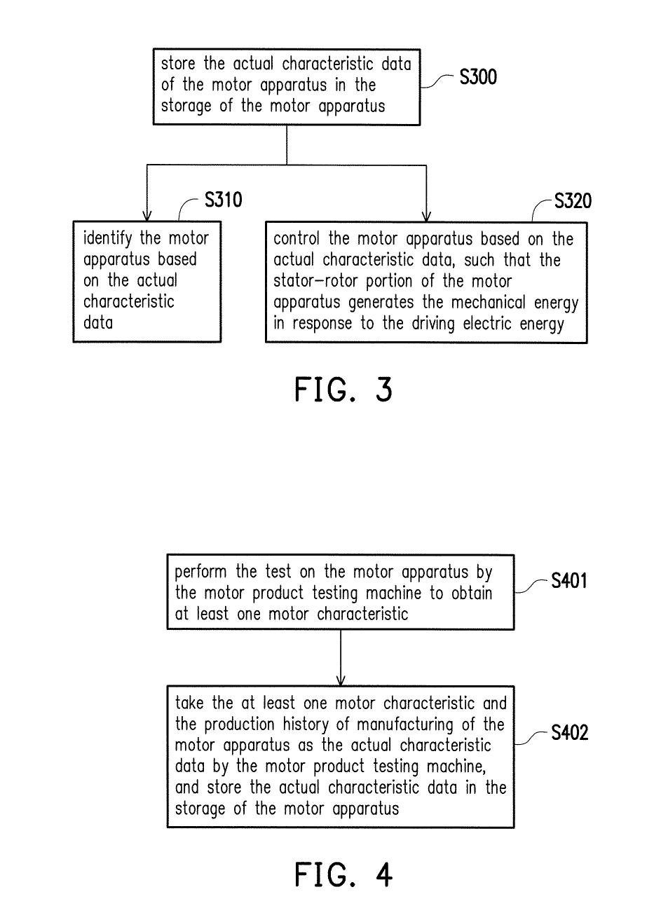

Hereinafter, referring to FIG. 3, FIG. 3 is a flowchart showing a motor control method according to an embodiment of the invention, which is adapted for the motor system 100 of FIG. 1 or the motor system 200 of FIG. 2. To facilitate the explanation, the flowchart of FIG. 3 is described hereinafter with reference to the motor system 200 of FIG. 2 as an example. The motor control method of FIG. 3 includes the following steps. First, in Step S300, the actual characteristic data RCD of the motor apparatus 220 is stored in the storage 123 of the motor apparatus 220. Then, in Step S310, the motor apparatus 220 is identified based on the actual characteristic data RCD, or in Step S320, the motor apparatus 220 is controlled based on the actual characteristic data RCD, such that the stator-rotor portion 121 of the motor apparatus 220 generates the mechanical energy ME in response to the driving electric energy DE.

Referring to FIG. 2 to FIG. 4 hereinafter, FIG. 4 is a flowchart showing detailed steps of Step S300 of FIG. 3 according to an embodiment of the invention. As shown in FIG. 4, Step S300 (the step of storing the actual characteristic data RCD of the motor apparatus 220 in the storage 123 of the motor apparatus 220) may include the following detailed steps. First, in Step S401, the test is performed on the motor apparatus 220 by the motor product testing machine to obtain at least one motor characteristic. Then, in Step S402, the at least one motor characteristic and the production history of manufacturing of the motor apparatus 220 are taken as the actual characteristic data RCD by the motor product testing machine, and the actual characteristic data RCD is stored in the storage 123 of the motor apparatus 220.

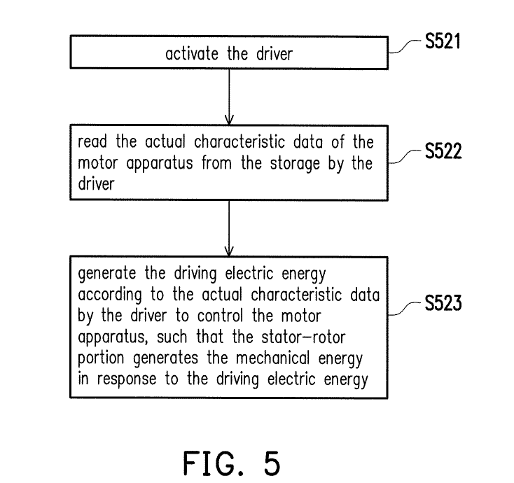

Referring to FIG. 2, FIG. 3, and FIG. 5 hereinafter, FIG. 5 is a flowchart showing detailed steps of Step S320 of FIG. 3 according to an embodiment of the invention. As shown in FIG. 5, Step S320 (the step of controlling the motor apparatus 220 based on the actual characteristic data RCD) may include the following detailed steps. First, in Step S521, the driver 240 is activated. Then, in Step S522, the actual characteristic data RCD of the motor apparatus 220 is read from the storage 123 by the driver 240. Next, in Step S523, the driving electric energy DE is generated according to the actual characteristic data RCD by the driver 240 to control the motor apparatus 220, such that the stator-rotor portion 121 generates the mechanical energy ME in response to the driving electric energy DE.

Other details of the motor control method according to the embodiments of the invention may be understood from the teaching, suggestion, and description of the embodiments and FIG. 1 and FIG. 2, and thus are not repeated here.

To sum up, in the motor system and the motor control method disclosed in the embodiments of the invention, the actual characteristic data of the motor apparatus is stored in the storage of the motor apparatus, and the stored actual characteristic data may serve as a basis of controlling the motor apparatus or identifying the motor apparatus, thereby optimizing performance of the motor system and facilitating tracking and clarifying the problem that the motor apparatus may have in the future.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

What is claimed is:

1. A motor system, comprising:
a motor apparatus, comprising:
a stator-rotor portion receiving driving electric energy; and
an encoder circuit electrically coupled to the stator-rotor portion and comprising a storage that stores actual characteristic data of the motor apparatus.

2. The motor system according to claim 1, further comprising:
a driver electrically coupled to the stator-rotor portion and the storage, wherein when the driver is activated, the driver reads the actual characteristic data of the motor apparatus from the storage, and generates the driving electric energy according to the actual characteristic data.

3. The motor system according to claim 1, wherein the actual characteristic data comprises at least one motor characteristic, wherein the at least one motor characteristic is a coil inductance, a coil impedance, a back electromotive force, a maximum rotating speed, a rated current, a rated torque, a maximum torque, a torque constant, or a power factor of the motor apparatus.

4. The motor system according to claim 1, wherein the actual characteristic data comprises a production history of manufacturing of the motor apparatus, wherein the production history comprises a production date, a production site, a motor type, or a product model number of the motor apparatus.

5. The motor system according to claim 4, wherein the actual characteristic data further comprises at least one motor characteristic, wherein the at least one motor characteristic is obtained through a test that a motor product testing machine performs on the motor apparatus via a driver, and the motor product testing machine stores the at least one motor characteristic and the production history to the storage via the driver.

6. The motor system according to claim 2, wherein the encoder circuit further comprises:
a feedback encoder coupled to the driver and detecting an operation state of the stator-rotor portion to generate a feedback detection signal,
wherein the driver further generates the driving electric energy according to the feedback detection signal.

7. A motor control method, comprising:
storing actual characteristic data of a motor apparatus in a storage of the motor apparatus; and
identifying the motor apparatus based on the actual characteristic data, or controlling the motor apparatus based on the actual characteristic data, such that a stator-rotor portion of the motor apparatus generates mechanical energy in response to driving electric energy.

8. The motor control method according to claim 7, wherein the step of storing the actual characteristic data of the motor apparatus in the storage of the motor apparatus comprises:
performing a test on the motor apparatus by a motor product testing machine to obtain at least one motor characteristic; and
taking the at least one motor characteristic and a production history of manufacturing of the motor apparatus as the actual characteristic data by the motor product testing machine, and storing the actual characteristic data in the storage of the motor apparatus.

9. The motor control method according to claim 7, wherein the step of controlling the motor apparatus based on the actual characteristic data, such that the stator-rotor portion generates the mechanical energy in response to the driving electric energy comprises:
activating a driver;
reading the actual characteristic data of the motor apparatus from the storage by the driver; and
generating the driving electric energy according to the actual characteristic data by the driver to control the motor apparatus, such that the stator-rotor portion generates the mechanical energy in response to the driving electric energy.

10. The motor control method according to claim 9, further comprising:
detecting an operation state of the stator-rotor portion by a feedback encoder of the motor apparatus to obtain a feedback detection signal; and
generating the driving electric energy according to the feedback detection signal by the driver to control the motor apparatus.
